(19) United States
(12) Patent Application Publication
(10) Pub. No.: US 2003/0194877 A1
(43) Pub. Date: Oct. 16, 2003

(54) Integrated etch, rinse and dry, and anneal method and system

(75) Inventors: Wai-Fan Yau, Los Altos, CA (US); Kevin P. Fairbairn, Los Gatos, CA (US); Michael Barnes, San Ramon, CA (US)

Correspondence Address: APPLIED MATERIALS, INC., 2881 SCOTT BLVD. M/S 2061, SANTA CLARA, CA, 95050, US

(73) Assignee: Applied Materials, Inc.

(21) Appl. No.: 10/124,437

(22) Filed: Apr. 16, 2002

(51) Int. Cl. H01L 21/302; H01L 21/461

(52) U.S. Cl. 438/745

(57) ABSTRACT

A method is provided processing workpieces including etching metal from a workpiece to define metal structures on the workpiece and transporting the workpiece through a controlled environment passage between an etch chamber and a wet clean module after the etching. A wet cleaning and drying of the workpiece is performed in the wet clean module to remove metal etch residues from the workpiece. The workpiece is transported through the controlled environment passage to an annealing chamber after wet cleaning. An annealing is performed and the metal structures are capped before exposing the workpiece to ambient atmosphere after etching, wet cleaning, and annealing. The capping may be performed in situ with the annealing in a CVD chamber. The metal etch process may include performing a timed etch for etching back a portion of a metal layer followed by a slow to endpoint etch with an endpoint signal, followed by a timed over etch. The workpiece is transferred from the etch chamber to the wet clean module for the wet cleaning after the such a process while maintaining a non-oxidizing atmosphere surrounding the workpiece so as to inhibit corrosion of the metal structures prior to the wet cleaning of the workpiece. The timed etch, the slow to endpoint etch, and the timed over etch is performed in three separate chambers. Or, the timed etch is performed in a first etch chamber and the slow to endpoint etch and the timed over etch are performed in a second etch chamber.

### BACKGROUND

In present metal etch processing systems, one, or possibly a few large wafers are processed in an etch chamber. A cassette having several wafers is loaded at an interface of the etch system and the wafers are moved, usually by robotic arm, from the cassette to the etch chamber for processing. Thus, wafers are removed from the cassette, placed in the etch chamber, etched, and then returned to the cassette. After all the wafers of a cassette have been processed in this manner, the cassette is removed from the etch processing system and carried by an operator to a stand alone wet clean system. Typically, the entire cassette of wafers are cleaned in a wet bath and then dried in preparation for inspection and/or testing.

A drawback with current metal etch processes is that metal structures on the surface of the wafer can degrade after removal of the cassette from an etch station. Highly reactive etch residues remaining on the surface of a wafer after an etch process can combine with gases and/or moisture of ambient atmosphere in a cleanroom to create corrosive agents on the surface of the wafer. For example, fluorine residue can combine with moisture to form hydrofluoric acid. Similarly, chlorine or bromine residues can form hydrochloric or bromic acids. Metal structures on the wafer are particularly susceptible to degradation as a result. Moreover, copper, which has advantages over other conductors in certain high performance devices, is more susceptible to corrosion than certain other conductors such as aluminum.

Furthermore, in current state of the art metal etch process, because of the small size of the metal structures created, even small amounts of oxidation or corrosion occurring during processing can perceptibly degrade device performance. Particularly in high performance devices, any degrading of device performance can result in failure of the device, thus reducing manufacturing yields and throughput.

In a conventional metal etch process, all the wafers of a cassette must be etched prior to removing the cassette to the wet bench for wafer cleaning. Thus, after etching, wafers sit idle in the cassette until all the wafers have been etched. If “lot” sizes are large, or several cassettes are loaded at once, the first wafers etched wait in the cassette for a significant amount of time after etching until all of the wafers have been etched before they are transported to a wet bench for cleaning.

After cleaning, the cassette is loaded at an inspection station to determine the quality of the etch process. If the inspection reveals that the process is not performing acceptably, the process can be corrected to improve its quality. While the cleaning and the inspection are being performed, one or more additional lots are being processed through the etch chamber. Thus, several lots can end up being processed with the unacceptable etch process before detection of a problem, resulting in additional lots that also must be discarded. Further, a significant amount of manufacturing time has been lost to unproductive processing.

Thus, what is needed is a metal etch method and system which improves the shelf life of wafers, and one which minimize chances of corrosion during wait times. Further, what is needed is an etch system or method that allows quick and reliable processing of wafers, reduces wafer idle time, and allows better process performance feedback.

### SUMMARY

In one implementation a method is provided processing workpieces including etching metal from a workpiece to define metal structures on the workpiece and transporting the workpiece through a controlled environment passage between an etch chamber and a wet clean module after the etching. A wet cleaning and drying of the workpiece is performed in the wet clean module to remove metal etch residues from the workpiece. The workpiece is transported through the controlled environment passage to an annealing chamber after wet cleaning. An annealing is performed and the metal structures are capped before exposing the workpiece to ambient atmosphere after etching, wet cleaning, and annealing. The capping may be performed in situ with the annealing in a CVD chamber.

The metal etch process may include an etch-back process including performing a timed etch for etching back a portion of a metal layer. Thereafter, a slow to endpoint etch is performed utilizing an endpoint signal to determine when a barrier layer is reached. Then, a timed over etch is performed for removing remaining portions of the metal layer capable of short circuiting the metal structures. The workpiece is transferred from the etch chamber to the wet clean module for the wet cleaning after the etch-back process while maintaining a non-oxidizing atmosphere surrounding the workpiece so as to inhibit corrosion of the metal structures prior to the wet cleaning of the workpiece.

In one implementation, the timed etch for etching back a portion of the metal layer is performed in a first etch chamber, the slow to endpoint etch is performed in a second etch chamber, and the timed over etch is performed in a third etch chamber. The workpiece is transferred between the first etch chamber, the second etch chamber, and the third etch chamber and from the third chamber to the wet clean module while maintaining a non-oxidizing atmosphere surrounding the workpiece.

In another implementation, the timed etch for etching back a portion of the metal layer is performed in a first etch chamber and the slow to endpoint etch and the timed over etch is performed in a second etch chamber.

The slow to endpoint etch may be performed with about a 1:1 selectivity between the metal layer and the barrier layer. The timed over etch may be performed with about a 1:1:1 selectivity between the barrier layer, the metal layer, and a dielectric material.

In one embodiment, an integrated metal etch station is provided including a factory interface adapted to receive a cassette of wafers, the factory interface is coupled to a controlled environment transport passage. A plurality of metal etch chambers are mounted to the controlled environment transport passage along with a wet clean module and a chemical vapor deposition chamber. A transport system located within the integrated metal etch station is capable of transporting a wafer between the factory interface, the plurality of metal etch chambers, the wet clean module, and the chemical vapor deposition chamber without exposing the wafers to ambient atmosphere.

The controlled environment transport passage may include a wet bench transport chamber and a metal etch preprocessing chamber coupled via an intermediate chamber. The factory interface, the wet clean module, and the chemical vapor deposition chamber are mounted to the wet bench transport chamber, and the plurality of metal etch chambers are mounted to the metal etch preprocessing chamber. Some embodiments may include a wafer monitor module coupled to the wet bench transport chamber.

### BRIEF DESCRIPTION OF THE DRAWINGS

FIG. 1 shows simplified plan view of an integrated etch station in accordance with an embodiment of the present invention.

FIG. 2 shows simplified plan view of an integrated etch station in accordance with an embodiment of the present invention.

FIG. 3 shows simplified plan view of an integrated etch station in accordance with an embodiment of the present invention.

FIGS. 4A and 4B show a partial cut away cross-section of a partially processed wafer.

### DESCRIPTION

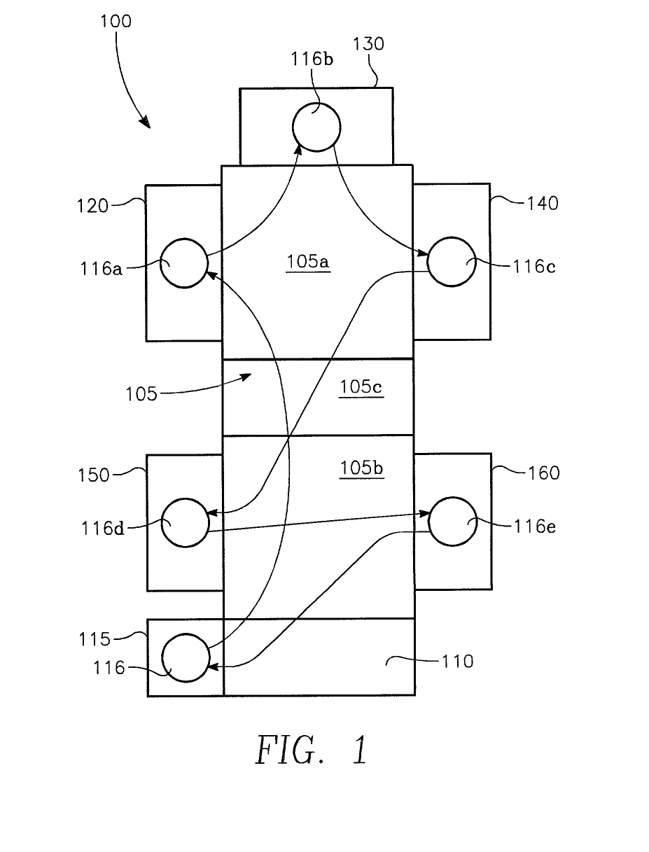

FIG. 1 shows an integrated metal etch, rinse and dry, and anneal station 100. A cassette or other wafer carrier 115 is mounted at a factory interface 110 of the integrated etch station 100. The factory interface opens to a transport chamber 105b of a wet clean section of the integrated etch station 100. A wet clean module 150 and an anneal module 160 are mounted to the wet clean transport chamber 105b. Plasma etch chambers 120, 130, and 140 are mounted to a preprocessing chamber 105a. Because metal etch chamber typically operates in about the 10⁻⁵ atmosphere range, pumping each wafer down from 1 atmosphere to 10⁻⁵ in a single chamber would take a long time. Thus, the etch preprocessing chamber pumps down to about 10⁻³ to 10⁻⁴ atmosphere to shorten pump down time in the etch chambers 120, 130 or 140. An intermediate chamber 105c, such as a pressure load lock chamber, may be located between the chambers 105b and 105a to provide an intermediate chamber between the wet clean transport chamber 105b and the etch preprocessing chamber 105a.

Together chambers 105b, 105c, and 105a form a controlled environment passage 105 for transporting the wafers 116 within the integrated metal etch station 100. A transport system (not shown), such as a robotic arm (not shown), is located within the wet clean section chamber portion 105b to move wafers 116 to and from the cassette 115, the intermediate chamber 105b, the wet clean module 150, and the anneal module 160. The transport system may include a second robotic arm (not shown), located within the etch preprocessing chamber portion 105a for moving wafers to and from the intermediate chamber 105c and the etch chambers 120, 130, and 140.

As depicted by the process flow arrows in FIG. 1, a wafer may be transported from the cassette 115 to one or more processing chambers 120, 130, and 140 for metal etch processing. After a wafer 116a, 116b, or 116c has been etched, it may be transported from the preprocessing chamber 105b the controlled atmosphere of the passage 105 to the wet clean module 150 without requiring an operator to carry them to a stand alone wet clean station. The wafers 116 may be wet cleaned after metal etching to remove any corrosive residues from the surface before exposing them to the ambient atmosphere. The wet clean module 150 rinses and dries the wafer 116d. After rinsing, the wafer 116d is blown dried, or spun in the wet clean module, to remove excess rinse solution from the wafer 116d.

After wet cleaning, the wafer 116d may be transported to an anneal module 160 mounted to the transport chamber 105b. Heating the wafer 116e in the anneal module 160 thoroughly drys and anneals the wafer 116e after rinsing and drying in the wet clean module. Thereafter, a capping process may be performed in situ in the anneal module to cap exposed metal structures. For this purpose a chemical vapor deposition chamber, may be utilized.

Wet cleaning the wafer 116d in the wet clean module 150 after processing with F, Cl, or Br, inhibits degradation of the wafer surface and improves the shelf life of the wafers after their removal from the controlled atmosphere of the integrated etch station 100. In addition, capping exposed metal structures after wet cleaning further improves self life and increases manufacturing yields. It ensures capping on surfaces free of corrosive etch residues to further reduce the potential for corrosion. Furthermore, in situ capping in the annealing chamber following the wet clean allows for improved wafer throughput.

In copper etch processes, wet cleaning followed by annealing and in situ capping helps mitigate the increased potential of corrosion of the copper. This is particularly important in copper etch processes which are performed at higher temperatures, such as in a range of about 100 degrees Celsius to about 350 degrees Celsius. Moreover, because the ambient shelf life is greatly improved there is no need for a stand alone wafer storage station to control corrosion of the copper wafers after removing the cassette from an etch station.

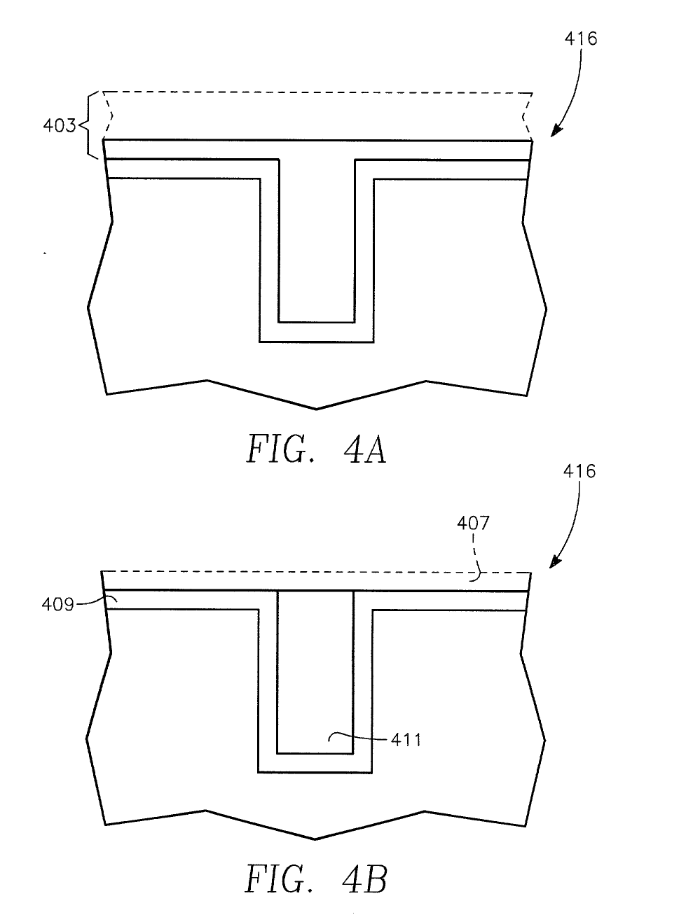

Referring to FIGS. 1, 4A and 4B, in one implementation utilizing the integrated metal etch station 100, an etch-back process performed utilizing plasma etch chamber 120 for a fast timed etch. The fast timed etch is performed to remove most of a conductive film 403. After the fast timed etch, the wafer 416 is transferred to another plasma etch chamber 130 where a slow-to-endpoint etch is performed to etch-back or remove the remaining conductive film 407 to define the conductor path (shown in side view as 411 in FIG. 4B). An endpoint signal is used to measure when a barrier layer film 409 is reached. For the slow-to-endpoint process selectivity can be 1:1 between the conductive film and the barrier film.

After the slow-to-endpoint etch, the wafer 416 can be transferred to another etch chamber 140 to perform an over etch. The over etch is performed to remove any remaining portions (not shown) of the conductor film 409 which could cause shorts between conductor paths.

The wafer 416 is transferred from the etch chamber 140 to the wet clean module 150 via the passage 105. A non-oxidizing atmosphere is maintained in all chambers 105a, 105b, and 105c of the passage 105. Thus, a low moisture content atmosphere is provided in the passage 105. In the wet clean module 150, a buffered solution is used to remove any chlorine content on conductors and insulating films. The wafer 416 is then dried, such as by spinning or by blow drying in the wet clean module 150.

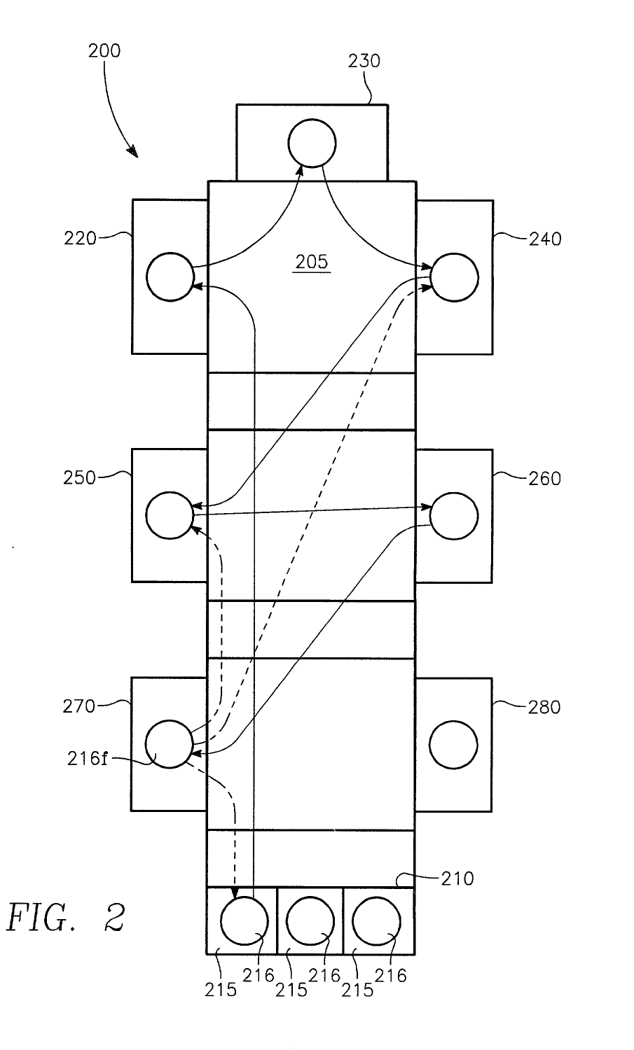

After wet cleaning and drying in the wet clean module 150, the wafer 416 is transferred to the anneal module 160 where the wafer 416 is heated typically to around 200 to 400 degrees Celsius. An in situ capping process may be performed at this time. The wafer 416 may then be returned to the cassette 115 or moved to a wafer monitor module 270 (shown and discussed with reference to FIG. 2 below) for inspection. Critical dimension measurements may be performed following capping after the etch-back process.

A chemical vapor deposition chamber or CVD chamber may be utilized as the anneal module 260 (shown and discussed with reference to FIG. 2 below) to allow deposition of a capping layer on metal structures after or during annealing. For example, conductors may be capped with silicon oxide, silicon nitride, silicon oxynitride, silicon carbide, or other dielectric at the end of the annealing process. Performing such an annealing and in situ capping after wet cleaning ensures capping on surfaces free of corrosive etch residues to further reduce the potential for corrosion. Performing the annealing an in situ capping also improves wafer throughput by providing fewer process steps, and by providing for process flow matching between the chambers and modules.

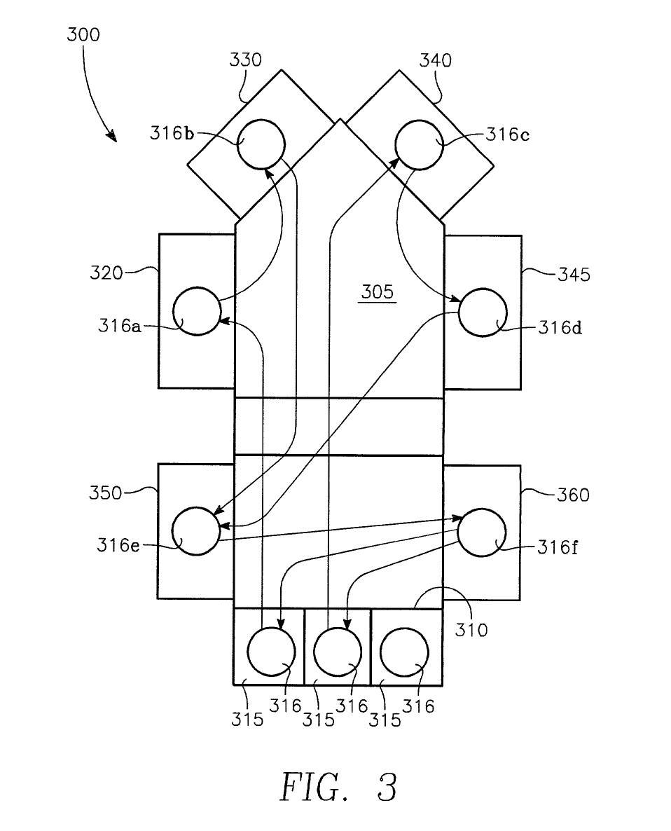

Referring to FIGS. 3, 4A and 4B, in an alternate implementation, a fast timed etch is performed in the plasma etch chamber 320 to remove most of a conductive film 403. After the fast timed etch, the wafer 416 is transferred to another plasma etch chamber 330 where a slow-to-endpoint etch is performed to remove the remaining conductive film 407 to define the conductor paths (a conductor path is shown in side view as 411 in FIG. 4B). An endpoint signal is used to measure when a barrier layer film 409 is reached. For the slow-to-endpoint process, selectivity can be 1:1 between the conductive film and the barrier film.

After the slow-to-endpoint etch, etching is continued in etch chamber 330 with a change in etch chemistry to etch an oxide/dielectric film and the barrier layer and the conductive film with a 1:1:1 selectivity. The underlying “conductive lines” are thus electrically isolated.

Although it is possible to move the wafer 416 to another processing chamber and perform a passivation process with NH₃ or H₂O vapor using microwave or rf enhancement, preferably the wafer 416 is transferred from the processing chamber 330 to the wet clean module 350. A buffered solution is used to remove any chlorine, fluorine, and/or bromine content left on conductor and insulating film. The wafer 416 is then dried, such as by spinning or by blow drying in the wet clean module 350. The wafer 416 is transferred to the anneal module 360 where the wafer 416 is heated typically to around 200 to 400 degrees Celsius. An in situ capping may be performed in the anneal module 360 at this time as discussed above. The wafer 416 may then be returned to the cassette 115, or moved to a wafer monitor module (not shown in FIG. 3) for inspection.

In this alternate implementation, metal etch chambers 340 and 345 may used to perform, in parallel, the same process as discussed with reference to metal etch chambers 320 and 330. Thereafter, the wafers may be transferred to the wet clean module 350 and the anneal module 360. Providing the anneal module 360 mounted with the wet clean station 350 allows matching of wafer throughput to achieve high manufacturing productivity. Without this, wafers must be collected in a cassette and transferred to a stand alone annealing station. This introduces delays, and wait time while all the wafers are loaded into the cassette. Further, the wafers are exposed to the ambient clean room environment during transportation and during any associated wait time prior to loading in the annealing chamber. Because the wafers have not been capped, corrosion can occur during this phase.

Shown in FIG. 1, a wafer 116 may be serially moved between etch chambers 120, 130, and 140 to perform different etch related processes on wafers 116a, 116b, or 116c. The arrows in FIG. 1 show an example of routing of a wafer through the integrated etch station 100. The etch chambers 120, 130, and 140 may perform different processes contemporaneously. Alternatively, all etch chambers 120, 130, and 140 may be utilized to perform the same processes contemporaneously on wafers 116a, 116b, and 116c.

As shown in FIG. 1, wafers 116a, 116b, and 116c can be etched while wafers 116d and 116e from the same cassette are wet cleaned and annealed. Thus, as opposed to conventional processes in which the first wafer of a lot can sit in the cassette 115 for up to several hours after etching and/or after wet cleaning, a method and system are provided that allow cleaning of wafers immediately after etching, while etching of the other wafers from the same cassette is occurring. Further, they allows annealing and capping immediately after wet cleaning. This reduces idle time to improve manufacturing productivity and yields.

Moreover, serial cleaning of the wafers 116 after etch allows closer monitoring and inspection of the process. As opposed to batch cleaning processes where several wafers from one or more cassettes are cleaned after all the wafers have been processed, cleaning of the wafer soon after etch can allow a more timely inspection of the process, as discussed below. Hence, problems with the etch process may be corrected more quickly.

FIG. 2 shows an integrated etch station 200 in accordance with an embodiment of the present invention. In the embodiment of FIG. 2, a wafer monitor module 270 is coupled to the passage 205. The wafer monitor module 270 may include wafer surface inspection devices, such a surface particle monitor and/or a critical dimension measuring device. One of these types of devices may be included in a separate module such as 280, also coupled to the passage 205. This embodiment allows the transport of wafers within the controlled environment between cassettes 215, the etch chambers 220, 230, or 240, the wet clean module 250, and the anneal module 260.

This configuration allows not only pre-etch pre-screening of wafers 216, the controlled environment between the wafer monitor module 270 and the wet clean and anneal modules 250 allows a more timely detailed and thorough post etch inspection of wafers 216. Wet cleaning of wafers 216 prior to inspection improves the quality and reliability of the inspection. If a wet clean is not performed prior to inspection, only a post etch screening inspection is performed, the wafers 216 are then carried by an operator to a stand alone wet bath, and then subsequently returned for a more detailed and thorough post etch inspection. Providing the wet clean module 250 allows a single, post etch inspection, which is detailed and thorough, to be performed. This improves processing time and inspection reliability. As such, earlier detailed detection and measurement of the wafer surface is possible.

The arrows in FIG. 2 show an example of routing of a wafer through the integrated etch station 200. As illustrated with dashed lines in FIG. 2, after inspection, a wafer 216f may be returned to the cassettes 215, or to any of the other processing chamber such as chamber 240, or to other modules such as 250 for further processing, or for corrective action, if necessary.

As discussed above, in some embodiments a deposition chamber, such as a CVD chamber, a plasma assisted deposition, or other deposition chamber may be included as part of the integrated etch station 200. For example, a CVD chamber could be utilized as the anneal module 260, and then utilized to deposit material after annealing. In metal etch applications, the CVD chamber could be utilized to cap the conductor with nitride or other dielectric after wet cleaning and annealing to reduce occurrence for corrosion. Critical dimension measurements may be performed after capping following an etch back as the capping does not change the width of the metal structure to be measured. Such measurements also may be performed following a pattern etch process with adjustment for capping or passivation layer thickness added to the width of the structure.

FIG. 3 shows an integrated etch station 300 in accordance with an embodiment of the present invention. Several cassettes 315 are mounted at a factory interface 310 provided near an end of the passage 305. The etch chambers 320, 330, 340, and 345 are coupled to the passage 305. The wet clean module 350 and the anneal module 360 are coupled to the passage 305. A controlled environment is provided within the passage 305 to allow the transport system (not shown) to transport wafers 316 between the cassette 315, the etch chambers 320, 330, 340, or 345, the wet clean module 350, and the anneal module 360.

In the embodiment of FIG. 3, depending of the number of processing steps, some of the wafers 316a and 316b could be processed through processing chambers 320 and 330 while others of the wafers 316c and 316d are processed in a parallel process in etch chambers 340 and 345. Thus, depending on the complexity of the structures to be formed, the processing chambers of the above described embodiments may be utilized in a serial mode, or in a parallel mode. Thereafter, the wafers 316b and 316d could be wet cleaned and annealed. The arrows in FIG. 3 show a example routing of a wafer through the integrated etch station 300.

In the implementations discussed above, the number of etch chambers and the routing of the wafers through the etch station is selected to substantially match the wafer throughput of each of the etch chambers and the wet clean and anneal modules. This allows fewer process steps, reduced wafer idle time, and improved throughput.

While the invention herein disclosed has been described by the specific embodiments and implementations, numerous modifications and variations could be made thereto by those skilled in the art without departing from the scope of the invention set forth in the claims.

What we claim is:

1. A method for processing workpieces comprising:
a) etching metal from a workpiece to define metal structures on the workpiece;
b) transporting the workpiece through a controlled environment passage between an etch chamber and a wet clean module after the etching;
c) wet cleaning and drying the workpiece in the wet clean module to remove metal etch residues from the workpiece;
d) transporting the workpiece through the controlled environment passage to an annealing chamber after wet cleaning;
e) annealing the metal structures; and
f) capping the metal structures before exposing the workpiece to ambient atmosphere after etching, wet cleaning, and annealing.

2. The method of claim 1 wherein annealing and capping are performed in situ.

3. The method of claim 2 wherein the annealing and the capping are performed using a chemical vapor deposition chamber.

4. The method of claim 1 wherein etching metal further comprises:
a) performing an etch-back process in at least one etch chamber to define the metal structures from a metal layer on the workpiece, the etch-back process comprising:
i) performing a timed etch for etching back a portion of the metal layer;
ii) performing a slow to endpoint etch comprising utilizing an endpoint signal to determine when a barrier layer is reached; and
iii) performing a timed over etch for removing remaining portions of the metal layer capable of short circuiting the metal structures; and
b) transferring the workpiece from the at least one etch chamber to the wet clean module for the wet cleaning after the etch-back process while maintaining a non-oxidizing atmosphere surrounding the workpiece so as to inhibit corrosion of the metal structures prior to the wet cleaning of the workpiece.

5. The method of claim 4 further comprising:
a) wherein performing a timed etch for etching back a portion of the metal layer comprises using a first etch chamber;
b) wherein performing a slow to endpoint etch comprises using a second etch chamber;
c) wherein performing a timed over etch comprises using a third etch chamber; and
d) wherein the workpiece is transferred between the first etch chamber, the second etch chamber, and the third etch chamber and from the third chamber to the wet clean module while maintaining a non-oxidizing atmosphere surrounding the workpiece.

6. The method of claim 5 wherein performing the slow to endpoint etch further comprises using about a 1:1 selectivity between the metal layer and the barrier layer.

7. The method of claim 6 wherein performing the timed over etch comprises performing the timed over etch with about a 1:1:1 selectivity between the barrier layer, the metal layer, and a dielectric material.

8. The method of claim 4 further comprising:
a) wherein performing a timed etch for etching back a portion of the metal layer comprises using a first etch chamber;
b) wherein performing a slow to endpoint etch comprises using a second etch chamber; and
c) wherein performing a timed over etch comprises using the second etch chamber.

9. The method of claim 8 wherein performing the slow to endpoint etch further comprises using about a 1:1 selectivity between the metal layer and the barrier layer.

10. The method of claim 9 wherein performing the timed over etch comprises changing the chemistry of second chamber after performing the slow to endpoint etch such that the timed over etch is performed with about a 1:1:1 selectivity between the barrier layer, the metal layer, and a dielectric material.

11. The method of claim 1 further comprising removing the workpiece from a the wet and performing the etching, the wet cleaning, the annealing, and the capping prior to returning the workpiece to the cassette.

12. The method of claim 11 further comprising:
a) wherein etching metal comprises etching one of copper or aluminum using at least one of fluorine, chlorine, or bromine in at least one plasma etch chamber;
b) wherein wet cleaning comprises rinsing the workpiece with a buffer solution and drying in the wet clean module;
c) wherein annealing and capping comprise using a chemical vapor deposition chamber; and
d) transporting the workpiece in a controlled environment passage when transferring between any of the cassette, the at least one etch chamber, the wet cleaning module, and the chemical vapor deposition chamber.

13. The method of claim 12 wherein capping comprises forming at least one of silicon oxide, silicon nitride, silicon oxynitride, or silicon carbide.

14. The method of claim 12 wherein etching metal comprises etching copper.

15. The method of claim 1 wherein etching metal comprises etching copper.

16. The method of claim 1 further comprising performing a critical dimension measurement after wet cleaning and annealing.

17. The method of claim 16 wherein performing a critical dimension measurement comprises performing the critical dimension measurement after capping.

18. A method for processing workpieces comprising:
a) etching metal from a workpiece using at least one of fluorine, chlorine, or bromine in at least one plasma etch chamber so as to define metal structures on the workpiece;
b) wet cleaning the workpiece in a wet clean module after etching the metal and prior to exposing the workpiece to an ambient atmosphere;
c) performing an annealing and an in situ capping of the metal structures in a chemical vapor deposition chamber following the wet cleaning of the workpiece and prior to exposing the workpiece to the ambient atmosphere; and
d) transporting the workpiece within a controlled environment passage between the at least one plasma etch chamber, the wet clean module, and the chemical vapor deposition chamber so as to inhibit corrosion of the metal structures.

19. The method of claim 18 wherein etching metal further comprises:
a) performing an etch-back process in at least one etch chamber to define the metal structures from a metal layer on the workpiece, the etch-back process comprising:
i) performing a timed etch for etching back a portion of the metal layer;
ii) performing a slow to endpoint etch comprising utilizing an endpoint signal to determine when a barrier layer is reached; and
iii) performing a timed over etch for removing remaining portions of the metal layer capable of short circuiting the metal structures; and
b) transferring the workpiece from the at least one etch chamber to the wet clean module for the wet cleaning after the etch-back process while maintaining a non-oxidizing atmosphere surrounding the workpiece so as to inhibit corrosion of the metal structures prior to the wet cleaning of the workpiece.

20. The method of claim 19 further comprising:
a) wherein performing a timed etch for etching back a portion of the metal layer comprises using a first etch chamber;
b) wherein performing a slow to endpoint etch comprises using a second etch chamber;
c) wherein performing a timed over etch comprises using a third etch chamber; and
d) wherein the workpiece is transferred between the first etch chamber, the second etch chamber and the third etch chamber and from the third chamber to the wet clean module while maintaining a non-oxidizing atmosphere surrounding the workpiece.

21. The method of claim 20 wherein performing the slow to endpoint etch further comprises using about a 1:1 selectivity between the metal layer and the barrier layer.

22. The method of claim 21 wherein performing the timed over etch comprises performing the timed over etch with about a 1:1:1 selectivity between the barrier layer, the metal layer, and a dielectric material.

23. The method of claim 19 further comprising:
a) wherein performing a timed etch for etching back a portion of the metal layer comprises using a first etch chamber;
b) wherein performing a slow to endpoint etch comprises using a second etch chamber; and
c) wherein performing a timed over etch comprises using the second etch chamber.

24. The method of claim 23 wherein performing the slow to endpoint etch further comprises using about a 1:1 selectivity between the metal layer and the barrier layer.

25. The method of claim 24 wherein performing the timed over etch comprises changes the chemistry of second chamber after performing the slow to endpoint etch such that the timed over etch is performed with about a 1:1:1 selectivity between the barrier layer, the metal layer, and a dielectric material.

26. The method of claim 18 further comprising removing the workpiece from a cassette and performing the metal etch, the wet cleaning, and the annealing and capping prior to returning the workpiece to the cassette.

27. The method of claim 26 wherein the capping comprises forming one of silicon oxide, silicon nitride, silicon oxynitride, or silicon carbide.

28. The method of claim 18 wherein etching metal comprises etching copper.

29. The method of claim 18 further comprising performing a critical dimension measurement after annealing and in situ capping.

30. A method for processing workpieces comprising:
a) removing a workpiece from a cassette and transporting the workpiece through a controlled environment passage to a metal etch chamber;
b) etching metal from a workpiece to define metal structures on the workpiece;
c) transporting the workpiece through the controlled environment passage to a wet clean module after the etching;
d) wet cleaning the workpiece in the wet clean module to remove etch residues from the workpiece;
e) transporting the workpiece through the controlled environment passage to an annealing chamber after wet cleaning;
f) annealing the workpiece in the annealing chamber after wet cleaning; and
g) capping the metal structures in the annealing chamber prior to returning the wafer to the cassette and prior to exposing the workpiece to the ambient atmosphere.

31. The method of claim 30 wherein the annealing and capping are performed in a chemical vapor deposition chamber.

32. The method of claim 31 further comprising:
a) wherein etching metal comprises etching one of copper or aluminum in using at least one of fluorine, chlorine, or bromine in at least one plasma etch chamber;
b) wherein wet cleaning comprises rinsing the workpiece with a buffer solution and drying in the wet clean module; and
c) wherein capping comprises forming one of silicon oxide, silicon nitride, silicon oxynitride, or silicon carbide.

33. The method of claim 32 wherein etching metal further comprises:
a) performing an etch-back process in at least one etch chamber to define the metal structures from a metal layer on the workpiece, the etch-back process comprising:
i) performing a timed etch for etching back a portion of the metal layer;
ii) performing a slow to endpoint etch comprising utilizing an endpoint signal to determine when a barrier layer is reached; and
iii) performing a timed over etch for removing remaining portions of the metal layer capable of short circuiting the metal structures; and
b) transferring the workpiece from the at least one etch chamber to the wet clean module for the wet cleaning after the etch-back process while maintaining a non-oxidizing atmosphere surrounding the workpiece so as to inhibit corrosion of the metal structures prior to the wet cleaning of the workpiece.

34. The method of claim 33 further comprising:
a) wherein performing a timed etch for etching back a portion of the metal layer comprises using a first etch chamber;
b) wherein performing a slow to endpoint etch comprises using a second etch chamber;
c) wherein performing a timed over etch comprises using a third etch chamber; and
d) wherein the workpiece is transferred between the first etch chamber, the second etch chamber and the third etch chamber and from the third chamber to the wet clean module while maintaining a non-oxidizing atmosphere surrounding the workpiece.

35. The method of claim 34 wherein performing the slow to endpoint etch further comprises using about a 1:1 selectivity between the metal layer and the barrier layer.

36. The method of claim 35 wherein performing the timed over etch comprises performing the timed over etch with about a 1:1:1 selectivity between the barrier layer, the metal layer, and a dielectric material.

37. The method of claim 33 further comprising:
a) wherein performing a timed etch for etching back a portion of the metal layer comprises using a first etch chamber;
b) wherein performing a slow to endpoint etch comprises using a second etch chamber; and
c) wherein performing a timed over etch comprises using the second etch chamber.

38. The method of claim 37 wherein performing the slow to endpoint etch further comprises using about a 1:1 selectivity between the metal layer and the barrier layer.

39. The method of claim 38 wherein performing the timed over etch comprises changes the chemistry of second chamber after performing the slow to endpoint etch such that the timed over etch is performed with about a 1:1:1 selectivity between the barrier layer, the metal layer, and a dielectric material.

40. The method of claim 30 wherein etching metal comprises etching copper.

41. The method of claim 30 further comprising performing a critical dimension measurement after annealing.

42. A method for processing a workpiece comprising:
a) removing the workpiece from a cassette;
b) performing an etch-back process in at least one etch chamber to define the metal structures from one of a metal layer on the workpiece, the etch-back process comprising:
i) performing a timed etch for etching back a portion of the metal layer;
ii) performing a slow to endpoint etch comprising utilizing an endpoint signal to determine when a barrier layer is reached; and
iii) performing a timed over etch for removing remaining portions of the metal layer capable of short circuiting the metal structures;
c) transferring the workpiece from the at least one etch chamber to a wet clean module for the wet cleaning after the etch-back process while maintaining a non-oxidizing atmosphere surrounding the workpiece so as to inhibit corrosion of the metal structures prior to the wet cleaning of the workpiece etching one of aluminum or copper using a plasma comprising at least one of fluorine, chlorine, or bromine to define a metal structure;
d) transporting the workpiece within a transport passage to the wet cleaning module after etching and while maintaining a non-oxidizing atmosphere in the transport passage so as to inhibit corrosion of the metal structures prior to wet cleaning the workpiece;
e) wet cleaning the workpiece in the wet clean module after performing the etch-back process and prior to exposing the workpiece to an ambient atmosphere;
f) transporting the workpiece within the transport passage to a chemical vapor deposition chamber after wet cleaning and while maintaining a non-oxidizing atmosphere in the passage so as to inhibit corrosion of the metal structure;
g) performing an in situ annealing and capping of the metal structure in the chemical vapor deposition chamber prior to exposing the workpiece to the ambient atmosphere;
h) wherein the capping comprises capping comprises forming one of silicon oxide, silicon nitride, silicon oxynitride, or silicon carbide; and
i) wherein etching, transporting the workpiece within the transport passage to the wet cleaning module, wet cleaning, transporting the workpiece within the transport passage to the chemical vapor deposition chamber, and performing the in situ annealing and capping are performed prior to returning the workpiece to the cassette.

43. The method of claim 42 further comprising:
a) wherein performing a timed etch for etching back a portion of the metal layer comprises using a first etch chamber;
b) wherein performing a slow to endpoint etch comprises using a second etch chamber;
c) wherein performing a timed over etch comprises using a third etch chamber; and
d) wherein the workpiece is transferred from the third chamber to the wet clean module while maintaining a non-oxidizing atmosphere surrounding the workpiece.

44. The method of claim 42 further comprising:
a) wherein performing a timed etch for etching back a portion of the metal layer comprises using a first etch chamber;
b) wherein performing a slow to endpoint etch comprises using a second etch chamber; and
c) wherein performing a timed over etch comprises using the second etch chamber.

45. The method of claim 42 wherein performing the slow to endpoint etch further comprises using about a 1:1 selectivity between the metal layer and the barrier layer.

46. The method of claim 45 further comprising etching a dielectric layer and the barrier layer and the conductive layer with about a 1:1:1 selectivity after performing the slow to endpoint etch.

47. The method of claim 42 wherein etching metal comprises etching copper.

48. The method of claim 42 further comprising performing a critical dimension measurement after annealing.

49. An integrated metal etch station comprising:
a) a factory interface adapted to receive a cassette of wafers, the factory interface being coupled to a controlled environment transport passage;
b) a plurality of metal etch chambers mounted to the controlled environment transport passage;
c) a wet clean module mounted to the controlled environment transport passage;
d) a chemical vapor deposition chamber mounted to the controlled environment transport passage; and
e) a transport system located within the integrated metal etch station such that the transport system is capable of transporting a wafer between the factory interface, the plurality of metal etch chambers, the wet clean module, and the chemical vapor deposition chamber without exposing the wafers to ambient atmosphere.

50. The integrated metal etch station of claim 49 wherein the controlled environment transport passage comprises a wet bench transport chamber and a metal etch preprocessing chamber coupled via an intermediate chamber.

51. The integrated metal etch station of claim 50 wherein the factory interface, the wet clean module, and the chemical vapor deposition chamber are mounted to the wet bench transport chamber, and wherein the plurality of metal etch chambers are mounted to the metal etch preprocessing chamber.

52. The integrated metal etch station of claim 51 further comprising a wafer monitor module coupled to the wet bench transport chamber.
